(19) United States
(12) Patent Application Publication
(10) Pub. No.: US 2008/0223609 A1
(43) Pub. Date: Sep. 18, 2008

(54) Electronic device and electronic component mounting method

(75) Inventor: Keiichi Yamamoto, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki-shi (JP)

(21) Appl. No.: 12/076,123

(22) Filed: Mar. 13, 2008

(30) Foreign Application Priority Data
Mar. 14, 2007 (JP) 2007-065222

(51) Int. Cl. H05K 1/16

(52) U.S. Cl. 174/260

(57) ABSTRACT

According to an aspect of an embodiment, an electronic device comprises a bonding material, an electronic component providing a plurality of pads on a bottom surface thereof, and a printed circuit board providing a plurality of pads on a surface thereof, at least one of the pads of the printed circuit board being connected to at least one of the pads of the electronic component by the bonding material so as to connect the printed circuit board with the electronic component electrically, wherein either the electronic component or the printed circuit board provides a dummy pad on which the bonding material is formed, the bonding material on the dummy pad butting against the other of the surfaces of the electronic component or the printed circuit board.

### BACKGROUND OF THE INVENTION

1. Field of the Invention

The present invention relates to a technique for mounting an electronic component(s) onto a printed circuit board by solder bonding.

2. Description of the Related Art

Electronic components (packages) each having at least one electrode (pad) on the bottom surface thereof and being mounted on a printed circuit board, are frequently used. Examples of the electronic components include a ball grid array (BGA), a chip scale package (CSP), a land grid array (LGA), a quad flat non-leaded package (QFN), a small outline non-leaded package (SON), and a leaded chip carrier (LCC).

The mounting of such an electronic component onto the printed circuit board is performed by using the following procedures. First, solder paste for bonding is printed on pads on the bottom surface of the electronic component, or on pads on the printed circuit board corresponding to the pads on the bottom surface of the electronic component. The electronic component is placed on the printed circuit board and heated in a reflow oven, whereby the electronic component is bonded to the printed circuit board together by solder for mounting.

Solder that bonds the pads on the printed circuit board and the pads of the electronic component together typically has a depressed shape like a drum. As a result, the distance (standoff) between the surface of the printed circuit board and the bottom surface of the electronic component decreases, and a short circuit between adjacent pads due to solder-solder contact is prone to occur. If a large standoff is ensured, short circuits due to solder-solder contact are reduced in the printed circuit board on which an electronic component is mounted, and thus, as well known, stresses are absorbed at joint portions of the solder to thereby prevent the solder from cracking or flaking-off, which leads to an improvement in product life.

However, with the reduction in the size and weight of electronic products, the minimization of the pitch between pads and the pad area is getting an increase in speed. In order to realize the reduction in the size and weight of electronic products, the supply amount of solder paste for bonding is necessitated to be reduced. The current mounting situation, therefore, has a tendency toward adopting a process going against an improvement in the reliability.

With such being the situation, the problem here is how to ensure a large standoff.

Regarding techniques for bonding electronic component(s) and a printed circuit board together by solder, patent documents have been disclosed, such as Japanese Unexamined Patent Application Publication Nos. 8-46313, 2001-94244, 5-160563, 2000-307237, and 7-38225.

### SUMMARY

According to an aspect of an embodiment, an electronic device comprises a bonding material, an electronic component providing a plurality of pads on a bottom surface thereof, and a printed circuit board providing a plurality of pads on a surface thereof, at least one of the pads of the printed circuit board being connected to at least one of the pads of the electronic component by the bonding material so as to connect the printed circuit board with the electronic component electrically, wherein either the electronic component or the printed circuit board provides a dummy pad on which the bonding material is formed, the bonding material on the dummy pad butting against the other of the surfaces of the electronic component or the printed circuit board.

### BRIEF DESCRIPTION OF THE DRAWINGS

FIG. 1 is a schematic view showing how electronic components are mounted onto a printed circuit board according to an embodiment of the present invention;

FIG. 2 is a diagram showing characteristic portions of an electronic device according to an embodiment of the present invention; and

FIG. 3 is a diagram showing a reflow process after solder paste has been supplied to pads according to an embodiment of the present invention.

### DESCRIPTION OF THE PREFERRED EMBODIMENTS

The present invention is directed to an electronic device including an electronic component having at least one pad for solder bonding, provided on the bottom surface thereof, and a printed circuit board having at least one pad to be solder-bonded to the at least one pad on the bottom surface of the electronic component, the at least one pad of the printed circuit board being provided on the surface thereof; and an electronic component mounting method for mounting, by solder bonding, an electronic component having at least one pad for solder bonding on the bottom surface thereof, onto a printed circuit board on the surface of which there is provided at least one pad to be solder-bonded to the at least one pad on the bottom surface of the electronic component.

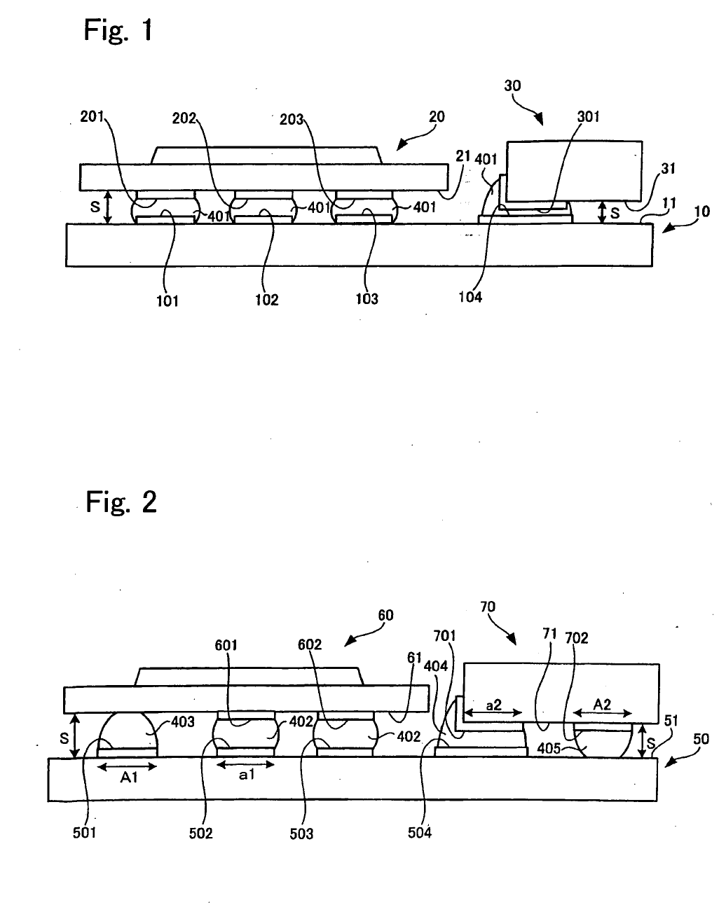

FIG. 1 is a schematic view showing how electronic components are mounted onto a printed circuit board.

In FIG. 1, a state is shown in which a BGA package electronic component 20 and an LCC package electronic component 30 are mounted onto the surface 11 of a printed circuit board (mother board) 10.

On the surface 11 of the printed circuit board 10, there are provided three pads 101, 102, and 103 for solder bonding to the BGA package electronic component 20, and one pad 104 for solder bonding to the LCC package electronic component 30. On the other hand, regarding the BGA package electronic component 20, three pads 201, 202, and 203 for solder bonding to the printed circuit board 10 are provided on the bottom surface thereof, and regarding the LCC package electronic component 30, one pad (as far as FIG. 1 shows) 301 for solder bonding to the printed circuit board 10 is provided on the bottom surface thereof.

The three pads 201, 202, and 203 on the bottom surface 21 of the electronic component 20 are, during mounting, respectively disposed at positions opposed to the three pads 101, 102, and 103 on the surface 11 of the printed circuit board 10. Likewise, the pad 301 on the bottom surface 31 of the electronic component 30 is, during mounting, disposed at a position opposed to the pad 104 on the surface 11 of the printed circuit board 10. Here, the electronic component 30 is the LCC package. The pad 301 extends as far as a side surface of the LCC package. However, here, it suffices for the pad only to exist on the bottom surface. It does not matter whether or not the pad extends up to the side surface.

Here, mutually opposing pads, i.e., the pads 101, 102, 103; and 104 on the printed circuit board 10, and the pads 201, 202, 203; and 301 of the electronic components 20 and 30 are bonded together, respectively, by a solder 401. In mounting the electronic components 20 and 30 onto the printed circuit board 10, solder paste is printed on the pad(s) of one side or both sides of the printed circuit board 10 and the electronic components 20 and 30, and the electronic components 20 and 30 are placed on the printed circuit board 10. Then, the electronic components 20 and 30 on the printed circuit board 10 are heated in the reflow oven, and the solder is solidified after having been melted. Thereby, the electronic components 20 and 30 are mounted onto the printed circuit board 10 by solder bonding.

Here, the solder that bonds pads 101, 102, 103; and 104 on the printed circuit board 10 and pads 201, 202, 203; and 301 of the electronic components 20 and 30 together, typically has a depressed shape like a drum, as shown in FIG. 1. As a result, the distances (standoff S) between the surface 11 of the printed circuit board 10 and the bottom surfaces 21 and 31 of the electronic components 20 and 30 decrease, short circuits between adjacent pads due to solder-solder contact are prone to occur, resulting in a significantly detrimental effect on the long term reliability of solder joint portions. On the other hand, if a large standoff is ensured, then, as is well known, short circuits due to solder-solder contact are reduced, and also stresses at the solder joint portions are absorbed, which prevents the solder from cracking or flaking-off, leading to improvement in product life.

To solve the above-described problem, a technique is proposed for ensuring a large standoff by arranging a plurality of dummy bumps made of resin or the like at four corners of the bottom surface of the electronic component to thereby causing the dummy bumps to function as spacers.

However, the adoption of the above-described method necessitates a process of arranging spacers on the bottom surface besides routine processes, thereby causing an increase in cost.

Hereinafter, an embodiment according to the present invention will be described with reference to the appended drawings.

FIG. 1 shows how electronic components are mounted onto a printed circuit board, and FIG. 2 shows characteristic portions of an electronic device according to the present invention.

As in the case of FIG. 1, FIG. 2 shows how a BGA package electronic component 60 and an LCC package electronic component 70 are mounted onto a printed circuit board (mother board) 50.

On the surface 51 of the printed circuit board 50, three pads pad 501, 502, and 503 are provided at positions opposed to the BGA package electronic components 60. Of these pads, two of the pads 502 and 503 are pads used for electric connection between the printed circuit board 50 and the electronic component 60. The pad 501 is not used for electric connection between the printed circuit board 50 and the electronic component 60. That is, the pad 501 is a dummy pad. In other words, on the bottom surface of the electronic component 60, the electronic component 60 has no pad at a position opposed to the pad 501. Also, the printed circuit board 50 has a pad 504. On the surface of the printed circuit board 50, the pad 504 is disposed at a position opposed to the LCC package electronic component 70. The pad 504 is one used for electric connection between the printed circuit board 50 and the electronic component 70.

On the bottom surface 61 of the electronic component 60, there are provided two pads 601 and 602. On the bottom surface 61 of the electronic component 60, the above-described two pads 601 and 602, respectively, are disposed at positions opposed to the pads 502 and 503 formed on the surface of the printed circuit board 50. Each of the sets of the pad 601 and pad 502; and the pad 602 and the pad 503 is bonded using a solder 402. In contrast, as described above, on the bottom surface of the electronic component 60, no pad is provided at a position opposed to the pad 501. A solder particle 403 for bonding the printed circuit board 50 and the electronic component 60 together makes a direct contact with the bottom surface 61 of the electronic component 60. As a result, the solder particle 403 supplied to the pad 501 formed on the printed circuit board 50 takes a round shape on the side of the printed circuit board 50. The solder particle 403 pushes up the electronic component 60 by the round tip thereof, to thereby form a large standoff S between the printed circuit board 50 and the electronic component 60. Here, the area (here, shown as a size A1) of the pad 501 serving as a dummy pad is made smaller than the area (here, shown as a size a1) of the other pads 502 and 503 on the printed circuit board 50 (i.e., A1<a1). During the mounting of the electronic component 60, the pads 501, 502, and 503 are supplied with a mutually equal amount of solder paste. Since the area of the pad 501 serving as a dummy pad is smaller than the area of the other pads 502 and 503 for electrically connecting the printed circuit board 50 and the electronic component 60, on the pad 501, the solder particle 403 having a larger height than that of the solder particles 402 formed on the pads 502 and 503 is formed by the melting and solidification of the solder, thereby more pushing up the standoff S.

Also, on the bottom surface 71 of another electronic component 70 of LCC package, there are provided two pads 701 and 702. On the bottom surface 71 of the electronic component 70, the pad 701 is disposed at a position opposed to the pad 504 formed on the surface of the printed circuit board 50. The pad 701 and the pad 504 are electrically connected by a solder particle 404 formed by the supply, melting, and solidification of solder paste. In contrast, the pad 702 is a dummy pad. On the surface 51 of the printed circuit board 50, no pad is formed at a position opposed to the pad 702. Therefore, solder paste is supplied to the pad 702 and after having been melted, it is solidified, to thereby form a solder particle 405 having a shape round on the side of the printed circuit board 50. The solder particle 405 pushes down the printed circuit board 50 by the round tip thereof to thereby form a large standoff S between the printed circuit board 50 and the electronic component 70. Here, the area (here, shown as a size A2) of the pad 702 is made smaller than the area (here, shown as a size a2) of the other pad 701 (i.e., A2<a2). During the mounting of the electronic component 70, all pads regarding the electronic component 70 are supplied with a mutually equal amount of solder paste. Since the area of the pad 702 is smaller than the area of the other pad 701 for electrically connecting the printed circuit board 50 and the electronic component 70, on the pad 702, a solder particle 405 having a larger height than that of the solder particles 404 formed on the pad 701 is formed by the melting and solidification of solder, thereby more pushing up the standoff S.

FIG. 2 shows an example in which a dummy pad is formed on each of the printed circuit board and the electronic component. Dummy pads may be provided only on the printed circuit board or may be provided only on the electronic component(s). Also, it is preferable that, for example, one dummy pad is provided at each of the four corners of the bottom surface of the electronic component, i.e., a total of four dummy pads are provided thereat, or that more than four dummy pads be provided. Providing at least three dummy pads on one electronic component allows the electronic component to be mounted in parallel to the printed circuit board without inclining. Furthermore, the more the number of electronic components, the more strongly acts the force for pushing up the standoff S between the printed circuit board and the electronic component.

The standoff between the printed circuit board and the electronic component depends on the weight of a target component, the number of pads, the pad area, the amount or kind of supply solder. However, the height of the standoff can be controlled by adjusting the diameter of dummy pads, the number thereof, and the paste amount to be supplied. Specifically, in a 72-pin QFN component with a size of 10 mm square, ten dummy pads with a diameter of 0.3 mm are installed on the mother board side. On each of the installation portions of the dummy pads, a metal mask (thickness: 0.12 mm) that is about 20 percent larger than the dummy pads is perforated. When no dummy pad is provided, the standoff between the printed circuit board and the electronic component is 30 to 50 μm, but it has been ascertained that the installation of dummy pads under the above-described conditions allows the standoff between the printed circuit board and the electronic component to be increased up to 70 to 90 μm. Also, it has been demonstrated that the installation of still more dummy pads or the control of solder amount allows the standoff between the printed circuit board and the electronic component to be even more increased.

In an electronic component with bottom electrodes, when there is little handoff for solder bonding (0 to 20 μm), a concentrated stress applied to the terminal electrode of the component is about 150 to 200 MPa. According to long-term reliability tests, it has been found that the time period until the solder junctions in the above-described component with bottom electrodes arrive at crack failure is very short. On the other hand, in the present invention, installing dummy pad(s) on either of the printed circuit board and the electronic component or both of them and thereupon making solder bonding to ensure a solder bonding standoff of about 150 μm, relaxes the concentrated stress down to 50 to 70 MPa. In the long-term reliability tests, it has been ascertained that the time period until the solder junctions arrive at crack failure is 50 to 60 times longer than the above-described former case.

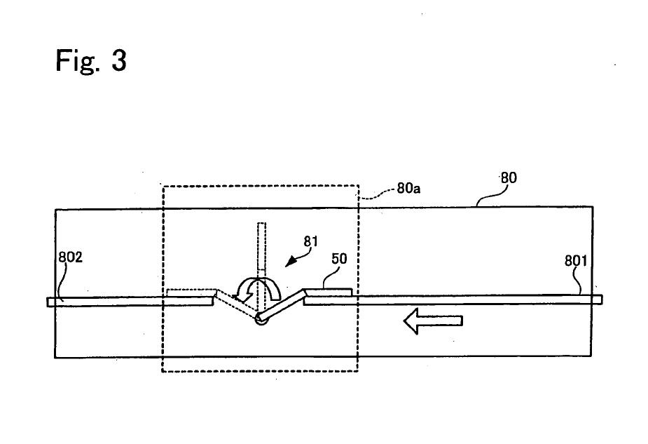

FIG. 3 is a diagram showing a reflow process after solder paste has been supplied to pads.

As shown in FIG. 3, the electronic component 60 and the electronic component 70 to be mounted onto the printed circuit board 50 shown in FIG. 2, are put on an entrance-side conveyor 80, and conveyed into a reflow oven 80 to arrive at a main heating zone 80a. Solder paste has already been supplied between the printed circuit board 50 and the electronic components 60 and 70. The solder paste is melted by its arrival at the main heating zone 80a. In the main heating zone 80a, a substrate reversing mechanism 81 lifts the printed circuit board 50, then slowly reverses it, and the substrate reversing mechanism 81 puts it on an exit-side conveyor 802. The exit-side conveyor 802 supports only the printed circuit board 50 in the reversed state so that the self-weights of the electronic components 60 and 70 are applied to the electronic components 60 and 70 on the printed circuit board 50. The melting temperature of the solder at this time is restrained to a temperature level so as to maintain the viscosity of the solder to such an extent that the solder does not drop off the printed circuit board 50 with the electronic components 60 an 70 reversed. The exit side conveyor 802 puts the printed circuit board 50 thereon and conveys outside the reflow oven 80. The molten solder for bonding the printed circuit board 50 and the electronic components 60 and 70 become cold and solidified outside the reflow oven 80. Here, since the printed circuit board 50 is reversed, and the self-weights of the electronic components 60 and 70 are applied to the electronic component 60 and the electronic component 70 that are put on the printed circuit board 50, the molten solder is extended, thereby forming a higher standoff S.

The electronic component and the printed circuit board according to the present invention has at least one dummy pad for forming the above-described standoff, and the dummy pad connects with solder particle, and therefore, although the solder particle spreads on the dummy pad side, its tip side apart from the dummy pad has a round shape due to a surface tension, the standoff is enhanced correspondingly.

As described above, according to the electronic device of the present invention, either one of the bottom surface of the electronic component and the surface of the printed circuit board has at least one dummy pad that is absent at an opposed position on the other of the surfaces, and a solder particle is connected to the at least one dummy pad, whereby the standoff can be effectively enhanced without increasing the supply amount of solder paste for bonding the electronic component and the printed circuit board together.

What is claimed is:

1. An electronic device comprising:
a bonding material;
an electronic component providing a plurality of pads on a bottom surface thereof; and
a printed circuit board providing a plurality of pads on a surface thereof, at least one of the pads of the printed circuit board being connected to at least one of the pads of the electronic component by the bonding material so as to connect the printed circuit board with the electronic component electrically,
wherein either the electronic component or the printed circuit board provides a dummy pad on which the bonding material is formed, the bonding material on the dummy pad butting against the other of the surfaces of the electronic component or the printed circuit board.

2. The electronic device according to claim 1,
wherein the bonding material has surface shape as a result of reflow treatment of the electronic device.

3. The electronic device according to claim 1,
wherein the bottom surface of the electronic component provides the dummy pad.

4. The electronic device according to claim 1,
wherein the surface of the printed circuit board provides the dummy pad.

5. The electronic device according to claim 1,
wherein at least three dummy pads are provided, the each dummy pads being connected with a bonding material.

6. The electronic device according to claim 1, an area of the dummy pad is smaller than an area of the pad.

7. An electronic device comprising:
an electronic component providing a plurality of pads on a bottom surface thereof; and
a printed circuit board providing a plurality of pads on a surface thereof, at least one of the pads of the printed circuit board being connected to at least one of the pads of the electronic component by solder bumps so as to connect the printed circuit board with the electronic component electrically,
wherein either the electronic component or the printed circuit board provides a dummy pad on which the solder bump is formed, the solder bump on the dummy pad bumping with the other of the surfaces of the electronic component or the printed circuit board.

8. The electronic device according to claim 7,
wherein the solder bumps have surface shapes as a result of reflow treatment of the electronic device.

9. An electronic component mounting method comprising the steps of:
melting a bonding material by heating, the bonding material having been supplied to a pad and a dummy pad provided on either a bottom surface of the electronic component or a surface of a printed circuit board, the electronic component being placed on the printed circuit board, and
reversing the printed circuit board before the bonding material becoming solidified while extending the bonding material.
